(19) United States
(12) Patent Application Publication
(10) Pub. No.: US 2024/0371945 A1
(43) Pub. Date: Nov. 7, 2024

(54) SILICON CARBIDE SUBSTRATE AND MANUFACTURING METHOD THEREOF

(71) Applicant: GlobalWafers Co., Ltd., Hsinchu (TW)

(72) Inventors: Ying-Ru Shih, Hsinchu (TW); Chih Shan Tan, Hsinchu (TW); Chung Chi Yang, Hsinchu (TW); Ching-Shan Lin, Hsinchu (TW)

(73) Assignee: GlobalWafers Co., Ltd., Hsinchu (TW)

(21) Appl. No.: 18/650,094

(22) Filed: Apr. 30, 2024

Related U.S. Application Data
(60) Provisional application No. 63/464,201, filed on May 5, 2023.

(51) Int. Cl. H01L 29/16; H01L 21/04; H01L 29/167

(52) U.S. Cl. CPC H01L 29/1608; H01L 21/0455; H01L 29/167

(57) ABSTRACT

A silicon carbide substrate includes an N-type silicon carbide substrate having a first surface and a second surface opposite to the first surface. The N-type silicon carbide substrate includes a semi-insulating silicon carbide region and an N-type silicon carbide region. The semi-insulating silicon carbide region extends inward from the first surface into the N-type silicon carbide substrate to a depth. The semi-insulating silicon carbide region includes nitrogen and a first dopant. The first dopant includes at least one of group VB elements, group VIIA elements, argon and silicon. The N-type silicon carbide region is adjacent to the semi-insulating silicon carbide region and includes nitrogen element.

### CROSS-REFERENCE TO RELATED APPLICATION

This application claims the priority benefit of U.S. provisional application Ser. No. 63/464,201, filed on May 5, 2023. The entirety of the above-mentioned patent application is hereby incorporated by reference herein and made a part of this specification.

### BACKGROUND

### Technical Field

The present invention relates to a silicon carbide substrate and its manufacturing method.

### Description of Related Art

Silicon carbide wafer is a third-generation semiconductor material. According to different electrical properties, silicon carbide wafer may be divided into low-resistivity N-type silicon carbide wafer and high-resistivity semi-insulating silicon carbide wafer. Generally speaking, the production cost of N-type silicon carbide wafer is low, but it does not meet the requirements of a high-resistivity substrate, and components placed on it are prone to leakage or short circuit problems. Semi-insulating silicon carbide wafer has an electrical resistivity greater than 10⁵ ohm-cm and is often used as a substrate for the growth of gallium nitride epitaxial layers. Gallium nitride is a third-generation semiconductor material. Because of its high operating frequency, it is very suitable for applications such as chargers, 5G base stations, and 5G communication equipment. Compared with silicon devices, gallium nitride devices may conduct electrons more efficiently and may withstand higher electric fields than silicon devices. However, due to the high production cost of semi-insulating silicon carbide wafers, many manufacturers are committed to developing methods to reduce their production costs.

### SUMMARY

The present invention provides a silicon carbide substrate and a manufacturing method thereof, the main advantage of which is that it may improve the matching between the silicon carbide substrate and the epitaxial layer above it while maintaining the low cost of the silicon carbide substrate. In this way, it can not only reduce the production cost of semiconductor devices, but also help improve the quality and performance of semiconductor devices.

At least one embodiment of the present invention provides a silicon carbide substrate, which includes an N-type silicon carbide substrate having a first surface and a second surface opposite to the first surface. The N-type silicon carbide substrate comprises a semi-insulating-type silicon carbide region and an N-type silicon carbide region. The semi-insulating-type silicon carbide region extends from the first surface into the N-type silicon carbide substrate to a depth. The semi-insulating-type silicon carbide region comprises nitrogen element and a first dopant. The first dopant includes at least one of group VB elements, group VIIA elements, argon and silicon. The N-type silicon carbide region is adjacent to the semi-insulating-type silicon carbide region and includes nitrogen element.

At least one embodiment of the present invention provides a manufacturing method of a silicon carbide substrate, comprising the following steps. An N-type silicon carbide substrate having a first surface and a second surface opposite to the first surface is provided. A doping process is performed on the first surface of the N-type silicon carbide substrate to form a semi-insulating-type silicon carbide region extending from the first surface into the N-type silicon carbide substrate to a depth. The semi-insulating-type silicon carbide region includes nitrogen element and a first dopant. The first dopant includes at least one of group VB elements, group VIIA elements, argon and silicon. The region of the N-type silicon carbide substrate that has not undergone the doping process includes an N-type silicon carbide region. The N-type silicon carbide region includes nitrogen element. An annealing process is performed on the semi-insulating-type silicon carbide region.

Based on the above, the first surface of the N-type silicon carbide substrate with lower production cost may be converted into a semi-insulating-type silicon carbide region with high electrical resistivity, thereby reducing the cost of producing semi-insulating silicon carbide. In some embodiments, the annealing process may be used to optimize the first surface, thereby improving the epitaxial quality of the subsequent epitaxial process.

### BRIEF DESCRIPTION OF THE DRAWINGS

FIGS. 1A to 1E are schematic cross-sectional views of a manufacturing method of a silicon carbide substrate according to an embodiment of the present invention.

FIG. 2 is a schematic cross-sectional view of a silicon carbide substrate according to another embodiment of the present invention.

FIG. 3A is a flow chart of a manufacturing method of a silicon carbide substrate according to an embodiment of the present invention.

FIG. 3B is a flow chart of a manufacturing method of a silicon carbide substrate according to another embodiment of the present invention.

### DESCRIPTION OF THE EMBODIMENTS

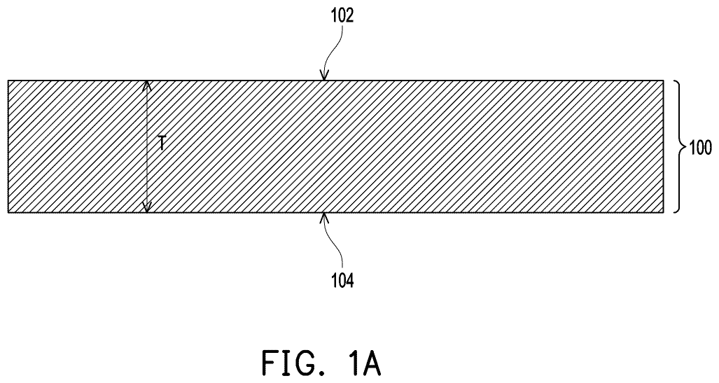

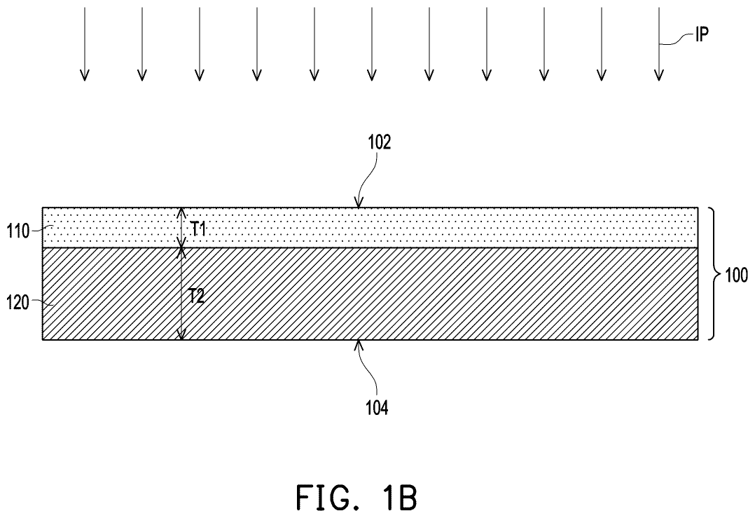

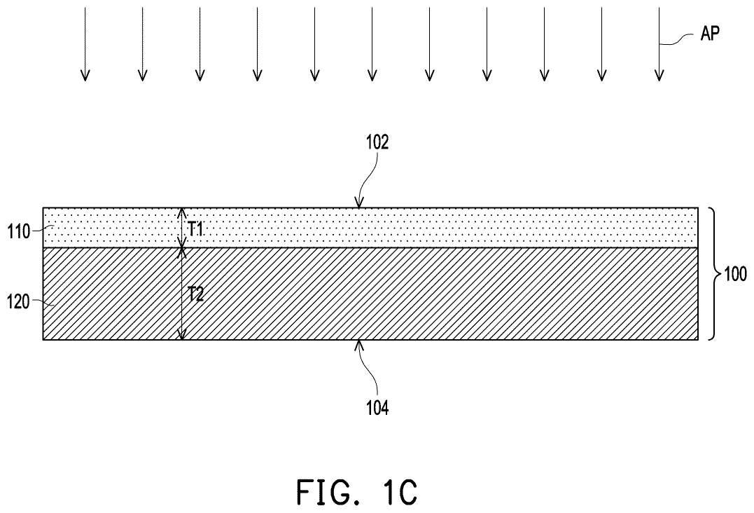

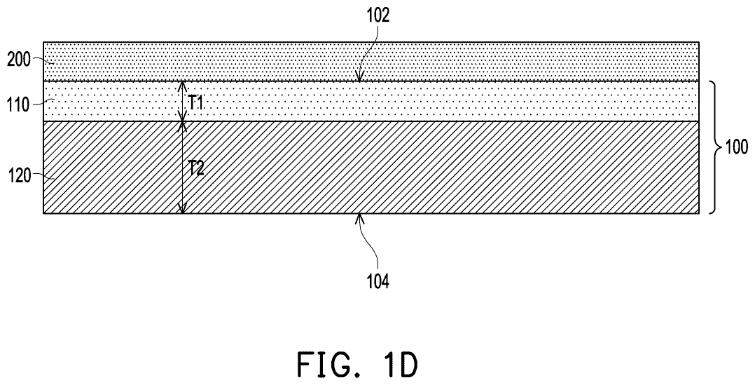

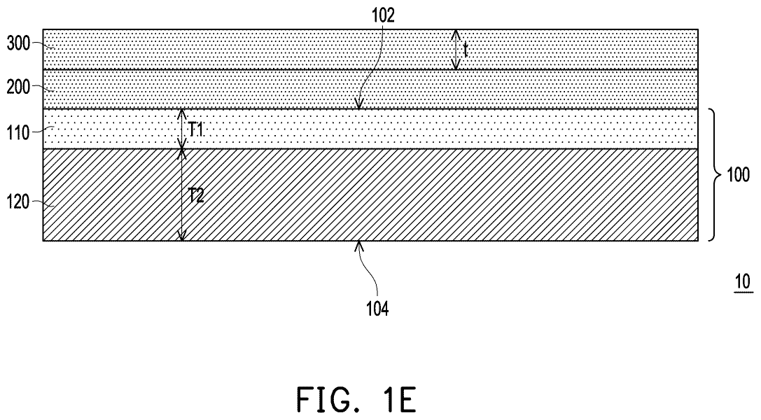

FIGS. 1A to 1E are schematic cross-sectional views of a manufacturing method of a silicon carbide substrate 10 according to an embodiment of the present invention. Referring to FIG. 1A, an N-type silicon carbide substrate 100 is provided. The N-type silicon carbide substrate 100 is, for example, a wafer, and has a first surface 102 and a second surface 104 opposite to the first surface 102. In some embodiments, the first surface 102 of the N-type silicon carbide substrate 100 is a silicon surface and has a low surface roughness Ra. Therefore, it is beneficial for the subsequent epitaxial layer to be formed on the first surface 102. In some embodiments, the surface roughness Ra of the first surface 102 is less than 1 nm, preferably less than 0.1 nm. The second surface 104 of the N-type silicon carbide substrate 100 is a carbon surface.

In some embodiments, the N-type silicon carbide substrate 100 includes nitrogen element. For example, a method of manufacturing N-type silicon carbide substrate 100 comprises the following steps. First, a powder containing silicon carbide is placed at the bottom of the crystal growth furnace, and a silicon carbide seed is placed at the top of the crystal growth furnace. Next, the silicon carbide powder is sublimated in a high-temperature and sealed crystal growth furnace. After the silicon carbide vapor condenses, it adheres to the silicon carbide seed, thereby obtaining a silicon carbide ingot. Then, the silicon carbide ingot is subjected to a series of cutting processes and grinding processes to obtain multiple silicon carbide wafers (i.e., the N-type silicon carbide substrate 100). In this embodiment, the crystal growth furnace contains nitrogen element (for example, the silicon carbide powder contains nitrogen element or a gas containing nitrogen element is applied into the crystal growth furnace), therefore, the final N-type silicon carbide substrate 100 includes nitrogen element.

In some embodiments, the concentration of nitrogen element in the N-type silicon carbide substrate 100 is 10¹⁷ cm⁻³ to 10²⁰ cm⁻³. In some embodiments, the thickness T of the N-type silicon carbide substrate 100 is about 200 μm to 1,000 μm. In some embodiments, the N-type silicon carbide substrate 100 comprises 4H silicon carbide or 6H silicon carbide. In some embodiments, the electrical resistivity of the N-type silicon carbide substrate 100 is 1.5×10⁻² ohm-cm to 2.5×10⁻² ohm-cm.

Referring to FIG. 1B, a doping process IP is performed on the first surface 102 of the N-type silicon carbide substrate 100 to form a semi-insulating-type silicon carbide region 110 extending from the first surface 102 into the N-type silicon carbide substrate 100 to a depth (e.g. less than or equal to 1 μm). The aforementioned depth may also be referred to as the thickness T1 of the semi-insulating-type silicon carbide region 110. The doping process IP implants the first dopant into the N-type silicon carbide substrate 100, so that the part of the N-type silicon carbide substrate 100 near the first surface 102 is converted to a semi-insulating-type silicon carbide region 110 with a higher electrical resistivity. The region of the N-type silicon carbide substrate 100 that has not undergone the doping process IP includes an N-type silicon carbide region 120. In some embodiments, the first dopant comprises at least one of group VB elements (e.g., niobium, vanadium, etc.), group VIIA elements (e.g., fluorine, etc.), argon, and silicon. In some embodiments, the concentration of nitrogen element in the N-type silicon carbide region 120 is 10¹⁷ cm⁻³ to 10²⁰ cm⁻³.

The concentration of the first dopant in the semi-insulating-type silicon carbide region 110 is greater than the concentration of the nitrogen element in the semi-insulating-type silicon carbide region 110. In some embodiments, the energy used in the doping process IP ranges from 10 keV to 2,500 keV. The doping dosage of the first dopant ranges from 10¹² to 5×10¹⁵ cm⁻². In some embodiments, the concentration of the first dopant in the semi-insulating silicon carbide region 110 increases as it approaches the first surface 102. In some embodiments, when the first dopant includes silicon, the silicon concentration in the semi-insulating-type silicon carbide region 110 may be higher than the silicon concentration in the N-type silicon carbide region 120.

Referring to FIG. 1C, an annealing process AP is performed on the semi-insulating-type silicon carbide region 120 or the entire N-type silicon carbide substrate 100. The annealing process AP may be performed using high temperature furnace annealing, laser annealing, microwave annealing, rapid thermal annealing or other suitable methods. In some embodiments, the N-type silicon carbide substrate 100 is heated in a high temperature furnace to 800° C. to 2000° C. (preferably 800° C. to 1600° C.) for 15 minutes to 60 minutes (preferably 20 minutes to 40 minutes). In some embodiments, by using a laser to heat the semi-insulating silicon carbide region 120, the laser may raise the temperature more quickly to a higher level (for example, 1000° C. to 2000° C.), thereby shortening the time required for the annealing process AP (for example, less than 10 minutes). In the preferred embodiment, the annealing process AP is a rapid thermal annealing process, with a temperature range of 800° C. to 1000° C., and the annealing time is within one minute.

Due to the inclusion of the first dopant in the semi-insulating silicon carbide region 110, the electrical resistivity of the semi-insulating silicon carbide region 110 is reduced. In some embodiments, the electrical resistivity of the semi-insulating-type silicon carbide region 110 is greater than 10⁵ ohm-cm, such as 10¹² ohm-cm to 10¹² ohm-cm. In some embodiments, the electrical resistivity of the N-type silicon carbide region 120 is 1.5×10⁻² ohm-cm to 2.5×10⁻² ohm-cm. In some embodiments, the electrical resistivity of the semi-insulating-type silicon carbide region 110 is 10⁶ to 10¹³ times that of the N-type silicon carbide region 120.

In some embodiments, the thickness T1 of the semi-insulating-type silicon carbide region 110 is 0.035% to 0.5% of the total thickness of the N-type silicon carbide substrate (ie, thickness T1 plus thickness T2). In some embodiments, the thickness T1 of the semi-insulating-type silicon carbide region 110 is less than or equal to 1 micrometer (preferably 350 nanometers to 400 nanometers), and the thickness T2 of the N-type silicon carbide region 120 is 200 to 1000 micrometers. It should be noted that the thickness of various components in the diagram is for illustration only and is not drawn to scale.

In some embodiments, the micro-pipe density (MPD) in the semi-insulating-type silicon carbide region 110 is less than 1 cm⁻². In some embodiments, the basal plane defect (BPD) in the semi-insulating-type silicon carbide region 110 is less than 500 cm⁻². In some embodiments, the threading screw dislocation (TSD) in the semi-insulating-type silicon carbide region 110 is less than 100 cm⁻².

Referring to FIG. 1D, a semi-insulating-type silicon carbide epitaxial layer 200 that contacts the first surface 102. In this embodiment, the semi-insulating silicon carbide region 110 formed by the doping process and the semi-insulating silicon carbide epitaxial layer 200 located above it exhibit superior lattice matching. As a result, optimized epitaxial quality may be achieved. For instance, the lattice constant of the semi-insulating silicon carbide region 110 formed by the doping process closely approximates the lattice constant of the semi-insulating silicon carbide epitaxial layer 200 located above it, thereby enhancing the epitaxial quality.

In some embodiments, the semi-insulating-type silicon carbide epitaxial layer 200 also comprises nitrogen element and a first dopant. However, the concentration of the nitrogen element in the semi-insulating-type silicon carbide region 110 is greater than the concentration of the nitrogen element in the semi-insulating-type silicon carbide epitaxial layer 200. In some embodiments, the concentration of the first dopant in the semi-insulating-type silicon carbide region 110 is greater than the concentration of the nitrogen element in the semi-insulating-type silicon carbide region 110 and the concentration of the nitrogen element in the semi-insulating-type silicon carbide epitaxial layer 200.

Referring to FIG. 1E, the semiconductor epitaxial layer 300 is directly formed on the side of the semi-insulating silicon carbide epitaxial layer 200 opposite to the N-type silicon carbide substrate 100, thus obtaining the silicon carbide substrate 10.

In some embodiments, the material of the semiconductor epitaxial layer 300 includes a nitride containing at least one of aluminum elements and gallium elements, such as AlInGaN, AlN, AlGaN, GaN, etc.

In some embodiments, the thickness t of the semiconductor epitaxial layer 300 is greater than 4 μm, preferably greater than 10 μm, for example, 10 μm to 20 μm.

In some embodiments, the semiconductor epitaxial layer 300 includes a second dopant. In some embodiments, the second dopant is, for example, comprising at least one of C, Fe, Co, Mn, Cr, V, and Ni. In some embodiments, the concentration of the second dopant in the semiconductor epitaxial layer 300 is greater than 10¹⁶ cm⁻³, for example, 10¹⁶ cm⁻³ to 1018 cm⁻³. In some embodiments, the electrical resistivity of the semiconductor epitaxial layer 300 is greater than 10⁵ ohm-cm, such as 10⁵ ohm-cm to 10¹² ohm-cm. In some embodiments, the semiconductor epitaxial layer 300 formed by the epitaxial process has excellent crystallinity. For example, an X-ray diffractometer is used to detect that the half-maximum width of the (002) plane of the semiconductor epitaxial layer 300 is less than 220 arcsec.

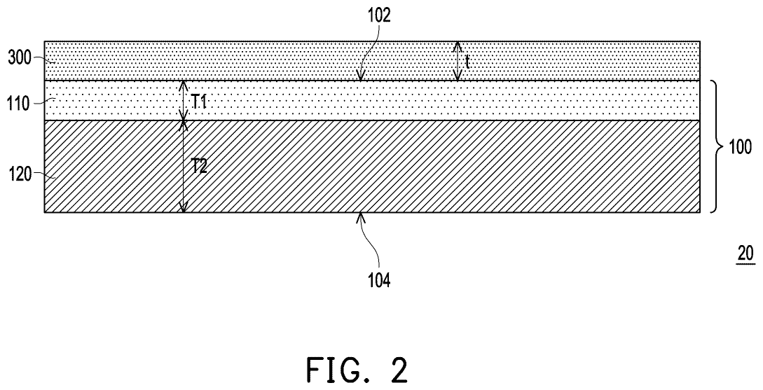

FIG. 2 is a schematic cross-sectional view of a silicon carbide substrate 20 according to another embodiment of the present invention. It should be noted herein that, in embodiments provided in FIG. 2, element numerals and partial content of the embodiments provided in FIG. 1A to FIG. 1E are followed, the same or similar reference numerals being used to represent the same or similar elements, and description of the same technical content being omitted. For a description of an omitted part, reference may be made to the foregoing embodiment, and the descriptions thereof are omitted herein.

The difference between the silicon carbide substrate 20 in FIG. 2 and the silicon carbide substrate 10 in FIG. 1E is that the silicon carbide substrate 20 does not comprise the semi-insulating-type silicon carbide epitaxial layer 200. In the silicon carbide substrate 20, the semiconductor epitaxial layer 300 is directly formed on the semi-insulating-type silicon carbide region 110 of the N-type silicon carbide substrate 100 (i.e., on the first surface 102).

In this embodiment, the semi-insulating silicon carbide region 110 formed by the doping process and the semiconductor epitaxial layer 300 located above it exhibit superior lattice matching. As a result, optimized epitaxial quality may be achieved. For instance, the lattice constant of the semi-insulating silicon carbide region 110 formed by the doping process closely approximates the lattice constant of the semiconductor epitaxial layer 300 located above it, thereby enhancing the epitaxial quality.

Furthermore, compared to the embodiment of additionally forming a semi-insulating silicon carbide epitaxial layer 200 on an N-type silicon carbide substrate 100, the silicon carbide substrate 20 in FIG. 2 has a lower production cost.

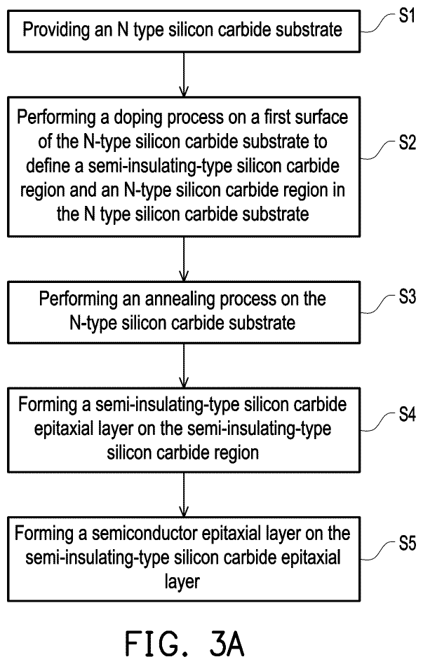

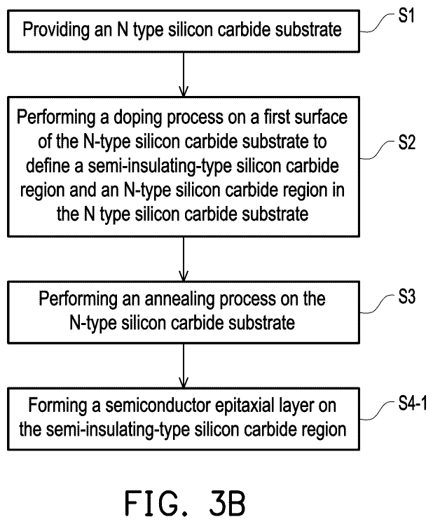

FIG. 3A is a flow chart of a manufacturing method of a silicon carbide substrate according to an embodiment of the present invention. Referring to step S1 of FIG. 3A and FIG. 1A, an N-type silicon carbide substrate 100 is provided. Referring to step S2 of FIG. 3A and FIG. 1B, a doping process IP is performed on the first surface 102 of the N-type silicon carbide substrate 100 to define a semi-insulating-type silicon carbide region 120 and an N-type silicon carbide region 110 in the N-type silicon carbide substrate 100. Referring to step S3 of FIG. 3A and FIG. 1C, an annealing process AP is performed on the N-type silicon carbide substrate 100. Referring to step S4 of FIG. 3A and FIG. 1D, a semi-insulating-type silicon carbide epitaxial layer 200 is formed on the semi-insulating-type silicon carbide region 110. Referring to step S5 of FIG. 3A and FIG. 1E, a semiconductor epitaxial layer 300 is formed on the semi-insulating-type silicon carbide epitaxial layer 200.

FIG. 3B is a flow chart of a manufacturing method of a silicon carbide substrate according to another embodiment of the present invention. Compared with the process shown in FIG. 3A, the semi-insulating-type silicon carbide epitaxial layer is not formed in the process shown in FIG. 3B. Specifically, after performing the annealing process AP on the N-type silicon carbide substrate 100 (as shown in step S3 of FIG. 3B and FIG. 1C), the semiconductor epitaxial layer 300 is formed on the semi-insulating-type silicon carbide region 110, as shown in step S4-1 of FIG. 3B and FIG. 2.

Hereinafter, the silicon carbide substrate proposed by the present invention will be described in detail through embodiments. However, the following embodiments are not intended to limit the present invention.

### Embodiment 1

An N-type silicon carbide substrate with a thickness of 322 μm is provided, where the electrical resistivity of the N-type silicon carbide substrate is 2×10⁻² ohm-cm. A doping process is performed on the silicon surface of the N-type silicon carbide substrate, where silicon is selected as the dopant, the doping energy is 100 keV, and the doping dosage is 5×10¹⁵ cm⁻². After forming a semi-insulating silicon carbide region with a depth of 350 nm within the N-type silicon carbide substrate using the doping process, a rapid thermal annealing process is performed on the N-type silicon carbide substrate, with the annealing temperature being 800° C. and the annealing time being one minute. The electrical resistivity of the resulting semi-insulating silicon carbide region is 5.7×10⁷ ohm-cm.

### Embodiment 2

An N-type silicon carbide substrate with a thickness of 322 μm is provided, where the electrical resistivity of the N-type silicon carbide substrate is 2×10⁻² ohm-cm. A doping process is performed on the silicon surface of the N-type silicon carbide substrate, where silicon is selected as the dopant, the doping energy is 100 keV, and the doping dosage is 5×10¹⁵ cm⁻². After forming a semi-insulating silicon carbide region with a depth of 400 nm within the N-type silicon carbide substrate using the doping process, a rapid thermal annealing process is performed on the N-type silicon carbide substrate, with the annealing temperature being 1000° C. and the annealing time being one minute. The electrical resistivity of the resulting semi-insulating silicon carbide region is 1.54×10⁸ ohm-cm.

In summary, in the embodiments of the present invention, a portion of the N-type silicon carbide substrate is converted to a semi-insulating silicon carbide region through a doping process. Since the semi-insulating silicon carbide region has a higher lattice matching with the epitaxial layer to be formed thereon, the quality of the epitaxial layer may be improved. In addition, compared with directly making a whole semi-insulating silicon carbide substrate, forming a semi-insulating silicon carbide region in the N-type silicon carbide substrate through the method of the embodiments of the present invention has a lower production cost.

What is claimed is:

1. A silicon carbide substrate, comprising:
an N-type silicon carbide substrate, having a first surface and a second surface opposite to the first surface, wherein the N-type silicon carbide substrate comprises:
a semi-insulating-type silicon carbide region, extending from the first surface into the N-type silicon carbide substrate to a depth, wherein the semi-insulating-type silicon carbide region comprises a nitrogen element and a first dopant, and the first dopant comprises at least one of group VB elements, group VIIA elements, argon and silicon; and
an N-type silicon carbide region, adjacent to the semi-insulating-type silicon carbide region, and comprising nitrogen element.

2. The silicon carbide substrate of claim 1, wherein the first dopant comprises at least one of niobium, vanadium, fluorine, argon and silicon.

3. The silicon carbide substrate of claim 1, further comprises:
a semi-insulating-type silicon carbide epitaxial layer in contact with the first surface; and
a semiconductor epitaxial layer in contact with a side of the semi-insulating-type silicon carbide epitaxial layer opposite to the N-type silicon carbide substrate.

4. The silicon carbide substrate of claim 3, wherein the semi-insulating-type silicon carbide epitaxial layer comprises nitrogen element, and a concentration of nitrogen element in the semi-insulating-type silicon carbide region is greater than a concentration of nitrogen element in the semi-insulating-type silicon carbide epitaxial layer.

5. The silicon carbide substrate of claim 1, wherein a concentration of the first dopant in the semi-insulating-type silicon carbide region is greater than a concentration of the nitrogen element in the semi-insulating-type silicon carbide region.

6. The silicon carbide substrate of claim 1, wherein the first surface is a silicon surface, and a roughness Ra of the first surface is less than 1 nm.

7. The silicon carbide substrate of claim 1, wherein a thickness of the semi-insulating-type silicon carbide region is 0.035% to 0.5% of a total thickness of the N-type silicon carbide substrate.

8. The silicon carbide substrate of claim 7, wherein the thickness of the semi-insulating-type silicon carbide region is less than or equal to 1 μm, and a thickness of the N-type silicon carbide region is 200 to 1000 μm.

9. The silicon carbide substrate of claim 1, wherein an electrical resistivity of the semi-insulating-type silicon carbide region is 10⁶ to 10¹³ times an electrical resistivity of the N-type silicon carbide region.

10. The silicon carbide substrate of claim 9, wherein the electrical resistivity of the semi-insulating-type silicon carbide region is greater than 10⁵ ohm-cm, and the electrical resistivity of the N-type silicon carbide region is 1.5×10⁻² ohm-cm to 2.5×10⁻² ohm-cm.

11. A manufacturing method of a silicon carbide substrate, comprising:
provide an N-type silicon carbide substrate, which has a first surface and a second surface opposite to the first surface;
performing a doping process on the first surface of the N-type silicon carbide substrate to form a semi-insulating-type silicon carbide region extending from the first surface into the N-type silicon carbide substrate to a depth, wherein the semi-insulating-type silicon carbide region comprises nitrogen element and a first dopant, and the first dopant comprises at least one of group VB elements, group VIIA elements, argon and silicon, and wherein a region of the N-type silicon carbide substrate that has not undergone the doping process comprises an N-type silicon carbide region, and the N-type silicon carbide region comprises nitrogen element; and
performing an annealing process on the semi-insulating-type silicon carbide region.

12. The manufacturing method of claim 11, further comprises:
directly forming a semi-insulating-type silicon carbide epitaxial layer on the first surface; and
directly forming a semiconductor epitaxial layer on a side of the semi-insulating-type silicon carbide epitaxial layer opposite to the N-type silicon carbide substrate.

13. The manufacturing method of claim 11, further comprises:
directly forming a semiconductor epitaxial layer on the first surface.
